(19) United States
(12) Patent Application Publication
(10) Pub. No.: US 2018/0130674 A1
(43) Pub. Date: May 10, 2018

(54) APPARATUS AND METHOD FOR PROCESSING SUBSTRATE

(71) Applicant: JUSUNG ENGINEERING CO., LTD., Gwangju-si, Gyeonggi-do (KR)

(72) Inventors: Tae Seong HAN, Gwangju-si, Gyeonggi-do (KR); Dae Bong KANG, Gwangju-si, Gyeonggi-do (KR); Jae Chan KWAK, Gwangju-si, Gyeonggi-do (KR); Ka Lam KIM, Gwangju-si, Gyeonggi-do (KR); Doo Young KIM, Gwangju-si, Gyeonggi-do (KR); Dong Won SEO, Gwangju-si, Gyeonggi-do (KR); Sang Du LEE, Gwangju-si, Gyeonggi-do (KR); Seong Kwang LEE, Gwangju-si, Gyeonggi-do (KR); Byoung Ha CHO, Gwangju-si, Gyeonggi-do (KR); Dong Seok CHUN, Gwangju-si, Gyeonggi-do (KR); Chul-Joo HWANG, Gwangju-si, Gyeonggi-do (KR)

(21) Appl. No.: 15/570,324

(22) PCT Filed: Apr. 18, 2016
(86) PCT No.: PCT/KR2016/004024

§ 371 Date: Oct. 27, 2017

(30) Foreign Application Priority Data
Apr. 28, 2015 (KR) 10-2015-0059987
Apr. 15, 2016 (KR) 10-2016-0046041

(51) Int. Cl. H01L 21/67; H01L 21/02; H01L 21/687; C23C 16/455; C23C 16/50; C23C 16/34

(52) U.S. Cl. CPC H01L 21/67017; H01L 21/02274; H01L 21/02208; H01L 21/02205; H01L 21/0217; H01L 21/02186; C23C 16/34; H01L 21/02178; H01L 21/02181; H01L 21/02183; H01L 21/68771; C23C 16/455; C23C 16/50; H01L 21/02189

(57) ABSTRACT

Disclosed are an apparatus and method for processing a substrate. The apparatus includes a chamber, a susceptor disposed in a lower portion of the chamber, a chamber lid disposed on the susceptor, a first source gas distributor installed in the chamber lid to distribute a source gas, a second source gas distributor installed in the chamber lid to distribute a source gas, and a first purge gas distributor installed in the chamber lid to distribute a purge gas. At least one substrate is disposed on the susceptor, and the first purge gas distributor is installed between the first and second source gas distributors.

### TECHNICAL FIELD

The present invention relates to a substrate processing apparatus, and more particularly, to a substrate processing apparatus which uses one or more gas distributors for forming a thin film on a substrate. Also, the present invention relates to a substrate processing method of forming a uniform and dense thin film on a substrate on which an ultramicro pattern is formed.

### BACKGROUND ART

Generally, a thin-film layer, a thin-film circuit pattern, or an optical pattern should be formed on a substrate surface for manufacturing a solar cell, a semiconductor device, a flat panel display device, etc. To this end, a semiconductor manufacturing process is performed, and examples of the semiconductor manufacturing process include a thin film deposition process of depositing a thin film including a specific material on a substrate, a photo process of selectively exposing a portion of a thin film by using a photosensitive material, an etching process of removing a thin film corresponding to the selectively exposed portion to form a pattern, etc.

The semiconductor manufacturing process is performed inside a substrate processing apparatus which is designed based on an optimal environment for a corresponding process, and recently, substrate processing apparatuses for performing a deposition or etching process based on plasma are much used.

Examples of the substrate processing apparatuses based on plasma include plasma enhanced chemical vapor deposition (PECVD) apparatuses for forming a thin film by using plasma, plasma etching apparatuses for etching and patterning a thin film, etc.

In semiconductor manufacturing processes and equipment of the related art, since a source gas remaining inside and on a pattern cannot be purged from a substrate on which the pattern which is complicated and high in aspect ratio is formed, a uniform thin film cannot be formed inside and on the pattern, and for this reason, a step coverage is not uniform between patterns or between an inner portion and an upper portion of the pattern, causing a reduction in process productivity.

### DISCLOSURE

### Technical Problem

An aspect of the present invention is directed to provide an apparatus and method for processing a substrate, which is suitable for forming a uniform and dense thin film on an ultramicro pattern formed on the substrate.

### Technical Solution

To achieve these and other advantages and in accordance with the purpose of the invention, as embodied and broadly described herein, there is provided an apparatus for processing a substrate including: a chamber; a susceptor disposed in a lower portion of the chamber, at least one substrate being disposed on the susceptor; a chamber lid disposed on the susceptor; a first source gas distributor installed in the chamber lid to distribute a source gas; a second source gas distributor installed in the chamber lid to distribute a source gas; and a first purge gas distributor installed in the chamber lid to distribute a purge gas, the first purge gas distributor being installed between the first and second source gas distributors.

The source gas may include one of a Si-containing gas, a Ti-containing precursor, Zr, Al, Hf, and Ta.

The first source gas distributor, the second source gas distributor, and the first purge gas distributor installed in the chamber lid may be radially installed in a direction toward an outer portion with respect to a center portion of the chamber lid.

An interval between center portions of the first source gas distributor and the first purge gas distributor installed in the chamber lid may be shorter than an interval between outer portions of the first source gas distributor and the first purge gas distributor.

The apparatus may further include: a second purge gas distributor installed in the chamber lid to distribute a purge gas; and a third purge gas distributor installed in the chamber lid to distribute a purge gas.

A gas distribution area of the second purge gas distributor or the third purge gas distributor may be wider than a gas distribution area of the first purge gas distributor.

A gas distribution flow rate of the second purge gas distributor or the third purge gas distributor may be higher than a gas distribution flow rate of the first purge gas distributor.

The apparatus may further include a plurality of reactive gas distributors installed in the chamber lid to distribute a reactive gas.

The reactive gas may include a nitrogen-containing gas or an oxygen-containing gas.

The plurality of reactive gas distributors may each include a plasma electrode.

In another aspect of the present invention, there is provided a method of for processing a substrate including: loading at least one substrate on a substrate supporting part installed in a chamber; distributing a source gas through a first source gas distributor installed on the at least one substrate; distributing a purge gas through a first purge gas distributor installed on the at least one substrate; and distributing a source gas through a second source gas distributor installed on the at least one substrate, wherein the distributing of the source gas through the first source gas distributor, the distributing of the purge gas through the first purge gas distributor, and the distributing of the source gas through the second source gas distributor are sequentially performed on the at least one substrate.

The source gas may include one of a Si-containing gas, a Ti-containing precursor, Zr, Al, Hf, and Ta.

The method may further include distributing a reactive gas through a plurality of reactive gas distributors installed in a chamber lid.

The reactive gas may include a nitrogen-containing gas or an oxygen-containing gas.

Each of the plurality of reactive gas distributors may generate plasma or a radical gas.

The method may further include distributing a purge gas through a second purge gas distributor and a third purge gas distributor installed in a chamber lid.

A gas distribution area of the second purge gas distributor or the third purge gas distributor may be wider than a gas distribution area of the first purge gas distributor.

A gas distribution flow rate of the second purge gas distributor or the third purge gas distributor may be higher than a gas distribution flow rate of the first purge gas distributor.

### Advantageous Effects

As described above, since the substrate processing apparatus according to the embodiments of the present invention includes a plurality of source gas distributors or a plurality of reactive gas distributors, a uniform thin film may be formed inside and on a pattern which is formed on a substrate, complicated, and high in aspect ratio.

Moreover, since the substrate processing apparatus according to the embodiments of the present invention includes a plurality of purge gas distributors, a source gas remaining inside and on a pattern may be appropriately purged (removed) from a substrate on which the pattern which is complicated and high in aspect ratio is formed, and thus, a uniform thin film may be formed inside and on the pattern.

Moreover, since the substrate processing apparatus according to the embodiments of the present invention includes a plurality of source gas distributors or a plurality of reactive gas distributors, a source gas is sufficiently adsorbed onto a substrate surface, or a reaction of the source gas and a reactive gas is sufficiently performed on the substrate surface, thereby enhancing the quality of a deposited thin film.

Moreover, in the substrate processing apparatus according to the embodiments of the present invention, a plasma electrode may be formed in a gas distributor, or by distributing an activated radical gas through a gas distributor distributes, a thin film may be formed on a substrate surface. Alternatively, a surface treatment may be performed on the thin film formed on the substrate surface. Accordingly, the quality of a deposited thin film is enhanced.

Moreover, in the substrate processing apparatus according to the embodiments of the present invention, a process of depositing a thin film on a substrate or an after-deposition surface treatment based on plasma may be repeatedly performed by using a gas distributor for deposition or a gas distributor configuring a portion or all of a plasma electrode, thereby enhancing the quality of the thin film deposited on the substrate.

Moreover, in the substrate processing apparatus according to the embodiments of the present invention, a gas distributor for deposition or a gas distributor configuring a portion or all of a plasma electrode may be used, and by repeatedly performing a process of depositing a thin film on a substrate or an after-deposition surface treatment which is performed by distributing a gas activated by plasma, the quality of the thin film deposited on the substrate is enhanced.

Moreover, in the substrate processing apparatus according to the embodiments of the present invention, a plasma electrode may be formed in a gas distributor separately from a gas distributor for deposition or an activated radical gas may be distributed through a gas distributor, and thus, by adding impurities into a distributed gas, the impurities may be injected into a thin film formed on a substrate in a deposition process or a surface treatment process, thereby enhancing the quality of a deposited thin film.

Moreover, since the substrate processing apparatus according to the embodiments of the present invention includes a plurality of source gas distributors or a plurality of reactive gas distributors, a source gas is sufficiently adsorbed onto a substrate surface, or a reaction of the source gas and a reactive gas is sufficiently performed on the substrate surface. Therefore, in depositing an atomic layer which is formed by rotating a gas distributor or a substrate holder, deposition of one atomic layer may be realized through one-time rotation, and the insufficiency of gas supply or a reaction duration caused by an increase in rotation speed may be offset, thereby enhancing the quality of a deposited thin film and increasing a deposition speed for the thin film.

Moreover, since the substrate processing apparatus according to the embodiments of the present invention includes a plurality of source gas distributors, a plurality of reactive gas distributors, or a radical gas distributor or a gas distributor including one or more plasma electrodes, the plurality of source gas distributors may distribute a metal precursor or a silicon-containing gas, or the plurality of reactive gas distributors may distribute an oxygen-containing gas or a nitrogen-containing gas, thereby enhancing the quality of a deposited thin film.

### DESCRIPTION OF DRAWINGS

FIG. 1 is a schematic cross-sectional view of a substrate processing apparatus according to an embodiment of the present invention.

FIG. 2 is a schematic cross-sectional view illustrating a plurality of substrates disposed on a susceptor of FIG. 1.

FIG. 3 is a schematic cross-sectional view of a plurality of gas distributors and a chamber lid of FIG. 1.

FIG. 4 is a schematic vertical cross-sectional view of a gas distributor illustrated in FIG. 1.

FIG. 5 is a schematic cross-sectional view illustrating a chamber lid and a plurality of gas distributors according to a second embodiment of the present invention.

FIG. 6 is a schematic cross-sectional view illustrating a chamber lid and a plurality of gas distributors according to a third embodiment of the present invention.

FIG. 7 is a schematic cross-sectional view of a plurality of gas distributors and a chamber lid of FIG. 6.

FIG. 8 is a schematic cross-sectional view illustrating a chamber lid and a plurality of gas distributors according to a fourth embodiment of the present invention.

FIG. 9 is a schematic cross-sectional view illustrating a chamber lid and a plurality of gas distributors according to a fifth embodiment of the present invention.

### MODE FOR INVENTION

Hereinafter, embodiments of the present invention will be described in detail with reference to the accompanying drawings. The present invention may be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

Referring to FIG. 1, a substrate processing apparatus 1 according to an embodiment of the present invention may have a cross-sectional surface of taken along line A-A′ in FIG. 4. In the substrate processing apparatus 1, a susceptor (a disk) 3 may be disposed in a lower portion of a chamber 2, and one or more substrates 100 may be disposed on the susceptor 3. A chamber lid 4 may be disposed on the susceptor 3, namely, in an upper portion of the chamber 2, and a plurality of purge gas distribution ports, a plurality of reactive gas distribution ports, and a plurality of source gas distribution ports may be installed in the chamber lid 4, whereby a structure where a plurality of gas distributors 5 are inserted through the distribution ports may be implemented. A substrate entrance 21 through which a substrate 100 is loaded or unloaded may be installed in one side surface of the chamber 2, and an exhaust port (not shown) may be installed in one side surface and a lower portion of the chamber 2.

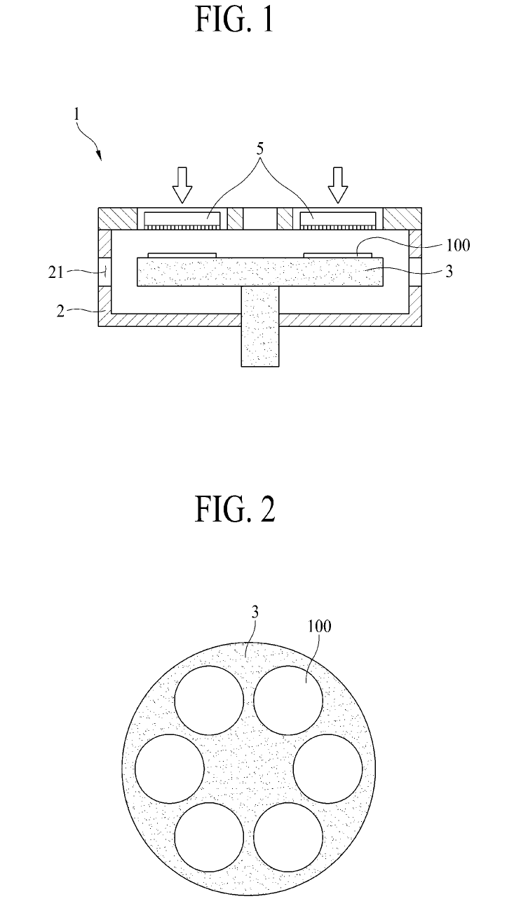

Referring to FIG. 2, in the substrate processing apparatus 1 according to an embodiment of the present invention illustrated in FIG. 1, a plurality of the substrates 100 may be disposed on the susceptor 3. As illustrated in FIG. 1, six the substrates 100 may be disposed on one the susceptor 3 in a concentric circle. If the plurality of substrates 100 are arranged at an equal interval or at a predetermined interval, the susceptor 3 may be provided in plurality, individually based on the number of the substrates 100. Also, the susceptor 3 may rotate with respect to a center of the susceptor 3. Therefore, the plurality of substrates 100 disposed on the susceptor 3 may rotate with respect to a center of the susceptor 3 or a center of the rotation.

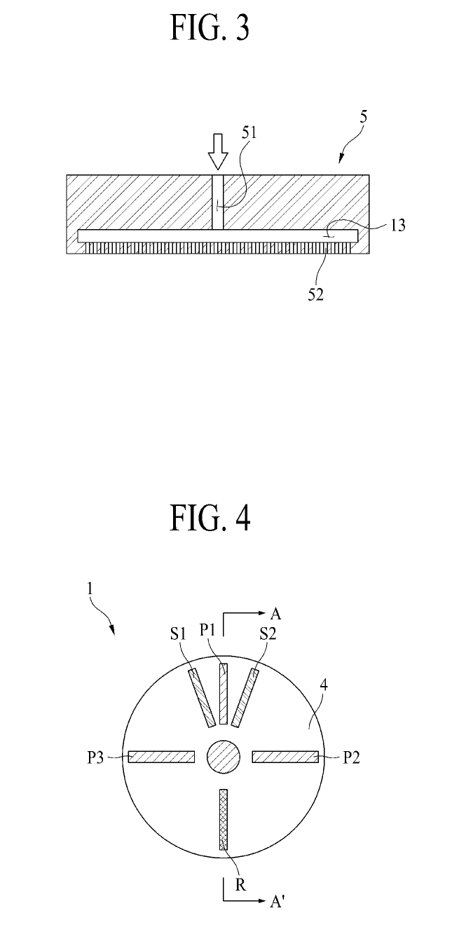

Referring to FIG. 3, one or more gas inflow ports 51 may be installed in the gas distributor 5, and a plurality of distribution holes 52 may be installed in the gas distributor 5. A gas may be injected through the gas inflow ports 51 in a top direction, a side direction, and a diagonal direction of the gas distributor 5. A hollow region may be in the gas distributor 5, and thus, a space 53 which enables the gas to be uniformly distributed may be disposed between the distribution hole 52 and the gas inflow port 51. Therefore, the gas which flows into the gas inflow port 51 before the gas is distributed through the distribution hole 52 may be fully filled into the space 53, and then may be distributed through the distribution hole 52.

Referring to FIG. 4, the plurality of gas distributors 5 may be radially disposed with respect to a center of the chamber lid 4 or may be disposed with respect to a center purge. In one or more of the plurality of gas distributors 5, the plurality of distribution holes 52 may be arranged in one or more rows in a radius direction from the center of the chamber lid 4. Alternatively, one or more of the plurality of gas distributors 5 may each be a showerhead type gas distributor 5 where the plurality of distribution holes 52 are formed toward the substrate 100 disposed on the susceptor 3 in the chamber lid 4.

The plurality of gas distributors 5 may be embedded into the chamber lid 4. Alternatively, a plurality of openings may be provided in the chamber lid 4, and the plurality of gas distributors 5 may be respectively inserted into the plurality of openings. Alternatively, a plurality of recessed portions may be provided in the chamber lid 4, and the plurality of gas distributors 5 may be respectively inserted into the plurality of recessed portions.

Referring to FIG. 4, a process sequence performed by the substrate processing apparatus 1 including the chamber lid 4 and the plurality of gas distributors 5 according to an embodiment of the present invention may correspond to a thin film deposition apparatus and a thin film deposition method which use a deposition cycle “first source gas distributor (S1)→first purge gas distributor (P1)→second source gas distributor (S2)→second purge gas distributor (P2)→reactive gas distributor (R)→third purge gas distributor (P3)”. A sequence of the deposition cycle according to an embodiment of the present invention may correspond to the above-described method, or processes may be performed in a sequence of a deposition cycle in a direction opposite thereto.

Referring to FIG. 4, in a gas distribution apparatus which is an apparatus for realizing a substrate processing process according to a first embodiment of the present invention, the plurality of source gas distributors S1 and S2 may be disposed, and the substrate 100 may pass through the plurality of source gas distributors S1 and S2 through one cycle or one-time rotation. Also, an interval between the source gas distributors S1 and S2 and the purge gas distributors P1 to P3 may be less than an interval between the reactive gas distributor R and the purge gas distributors P1 to P3. Also, a first source gas and a second source gas which are supplied may include the same gas. Also, the first source gas and the second source gas may differ in flow amount or flow rate.

Referring to FIG. 4, a source gas applied to the substrate processing process according to the first embodiment of the present invention may include a metal precursor, a reactive gas may include a nitriding gas or an oxidizing gas, and a purge gas may include a non-reactive gas. In detail, the source gas may include a titanium (Ti)-containing precursor, and the reactive gas may include a nitrogen (N)-containing gas. In detail, the source gas may include a zirconium (Zr) (or Al, Hf, Ta, etc.)-containing precursor, and the reactive gas may include an oxygen (O)-containing gas.

Referring to FIG. 4, the source gas applied to the substrate processing process according to the first embodiment of the present invention may include a silicon (Si)-containing gas (including organic silane, aminosilane, and/or the like), the reactive gas may include a nitriding gas or an oxidizing gas, and a purge gas may include a non-reactive gas. In detail, the source gas may include a Si-containing gas, and the reactive gas may include an N-containing gas or an O-containing gas.

Referring to FIG. 4, in the process according to the present embodiment, the source gas distributed from the source gas distributor S1 may include a metal precursor (a Ti-containing precursor). In detail, the source gas may include a Zr (or Al, Hf, Ta, etc.)-containing precursor. A first-order source gas process where the source gas distributed from the source gas distributor S1 is distributed onto the plurality of substrates may be performed. The source gas distributor S1 may distribute the source gas, the purge gas distributor P1 may distribute the purge gas. The purge gas distributed from the purge gas distributor P1 may remove (purge) some of the source gas distributed from the source gas distributor S1. In this case, in an upper portion of a pattern of the substrate which is closest to the purge gas distributor P1 and thus is exposed to a large amount of purge gas, a film may be the most removed (purged) by the purge gas, and in a lower portion and a side surface of the pattern of the substrate far away from the purge gas distributor P1, a film may be relatively less removed than the upper portion of the pattern. Subsequently, the source gas distributor S2 may distribute the source gas once more, and a second-order source gas distribution process may be performed on the substrate. The source gas may include a metal precursor (a Ti-containing precursor). In detail, the source gas may include a Zr (or Al, Hf, Ta, etc.)-containing precursor.

In a case where the source gas is distributed onto the substrate on which an ultramicro pattern is formed, when a film is uniformly deposited on an upper portion and a lower portion of the pattern and a side surface between the upper portion and the lower portion of the pattern, a step coverage is improved. When heights of films in the upper portion, the lower portion, and the side surface of the pattern of the substrate are uniform, a film may be fully deposited up to the lower portion of the substrate, and thus, a uniform film may be deposited between wafer patterns, whereby a semiconductor device operate normally.

Referring to FIG. 4, a first-stage process of loading at least one substrate on a substrate supporting part installed in the chamber may be performed. Subsequently, a second-stage process where the first source gas distributor S1 installed on the substrate 100 distributes the source gas may be performed. Subsequently, a third-stage process where the purge gas distributor P1 installed on the substrate 100 distributes the purge gas may be performed. Subsequently, a fourth-stage process where the second source gas distributor S2 installed on the substrate 100 distributes the source gas may be performed. The second-stage process, the third-stage process, and the fourth-stage process may be sequentially performed on the substrate. A uniform film may be uniformly deposited on an upper portion, a side surface, and a lower portion of a wafer pattern by sequentially performing the processes. The source gas applied to the present process may be a Ti-containing gas. A flow rate of the source gas distributed from the first source gas distributor S1 may be the same as or different from a flow rate of the source gas distributed from the second source gas distributor S2.

Referring to FIG. 4, the first source gas distributor 51, the second source gas distributor S2, and the first purge gas distributor P1 (e.g., the plurality of gas distributors 5) installed in the chamber lid 4 may be installed radially from one point of the center of the chamber lid 4, namely, the circle-shaped chamber lid 4. It is assumed that a center where one point is disposed in the chamber lid 4 having a radial shape of spreading radially from one point of a center of each of the first source gas distributor S1 and the first purge gas distributor P1 installed in the chamber lid 4 is a center portion, when an outer portion (i.e., a near-edge portion) of the chamber lid 4 is referred to as an outer portion, a distance between a center portion of the first source gas distributor 51 and a center portion of the first purge gas distributor P1 may be shorter than a distance between outer portions. On the other hand, a distance between near-edge portions (i.e., outer portions) may be longer than a distance of center portions. Also, a distance between the gas distributors 5 being short (close) may be referred to as the distance between the gas distributors 5 being narrow, and the distance between the gas distributors 5 being long (far away) may be referred to as the distance between the gas distributors 5 being wide.

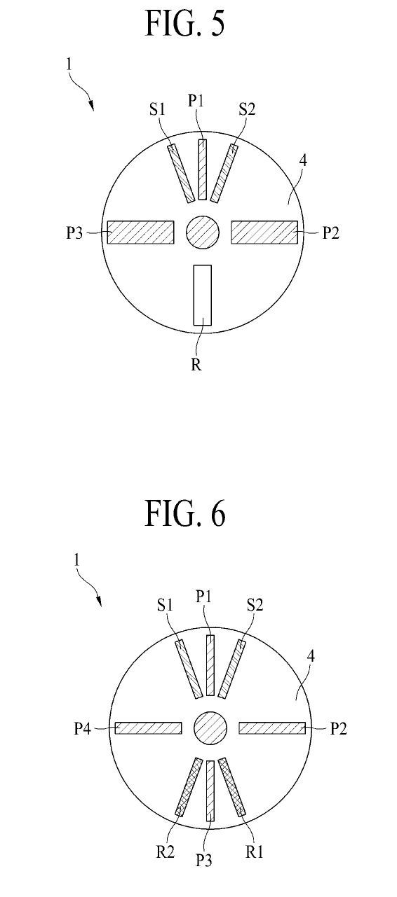

Referring to FIG. 5, a process sequence performed by the substrate processing apparatus 1 including the chamber lid 4 and the plurality of gas distributors 5 according to an embodiment of the present invention may correspond to a thin film deposition apparatus and a thin film deposition method which use a deposition cycle “first source gas distributor (S1)→first purge gas distributor (P1)→second source gas distributor (S2)→second purge gas distributor (P2)→reactive gas distributor (R)→third purge gas distributor (P3)”. In the thin film deposition apparatus, a gas distribution area of the second purge gas distributor (P2) or the third purge gas distributor (P3) may be wider than that of the first purge gas distributor (P1) between the first source gas distributor (S1) and the second source gas distributor (S2). In the thin film deposition apparatus, a gas distribution flow rate of the second purge gas distributor (P2) or the third purge gas distributor (P3) may be higher than that of the first purge gas distributor (P1) between the first source gas distributor (S1) and the second source gas distributor (S2). In the thin film deposition apparatus, the number of gas distribution holes of the second purge gas distributor (P2) or the third purge gas distributor (P3) may be larger than that of the first purge gas distributor (P1) between the first source gas distributor (S1) and the second source gas distributor (S2). A gas distribution area of the reactive gas distributor (R) may be wider than that of the first source gas distributor (S1) or the second source gas distributor (S2), and a gas distribution flow rate of the reactive gas distributor (R) may be higher than that of the first source gas distributor (S1) or the second source gas distributor (S2). The number of gas distribution holes of the reactive gas distributor (R) may be larger than that of the first source gas distributor (S1) or the second source gas distributor (S2). Also, the first purge gas distributor (P1) may be closer to the second source gas distributor (S2) disposed between the first purge gas distributor (P1) and the second purge gas distributor (P2) and may be closer to the first source gas distributor (S1) disposed between the first purge gas distributor (P1) and the third purge gas distributor (P3).

Referring to FIG. 5, an operation of depositing a substrate with a pattern formed thereon by using the substrate processing apparatus 1 according to an embodiment of the present invention may correspond to “first source gas distributor (S1)→operation (small purge) of purging a gas on a pattern→second source gas distributor (S2)→operation (large purge) of purging an upper portion and an inner portion of the pattern→reactive gas distributor (R)→operation of purging the upper portion and the inner portion of the pattern. In detail, the operation may correspond to “operation of distributing a Ti-containing gas onto the inner portion and the upper portion of the pattern→operation of purging the gas on the pattern or operation where a Ti gas in the pattern is not sufficiently removed→operation of distributing the Ti-containing gas onto the inner portion and the upper portion of the pattern→operation of purging the upper portion and the inner portion of the pattern→operation of distributing an N-containing gas onto the inner portion and the upper portion of the pattern→operation of purging the upper portion and the inner portion of the pattern”.

Referring to FIG. 6, a substrate processing apparatus 1 according to an embodiment of the present invention may perform a thin film deposition method which use a deposition cycle “first source gas distributor (S1)→first purge gas distributor (P1)→second source gas distributor (S2)→second purge gas distributor (P2)→first reactive gas distributor (R1)→third purge gas distributor (P3)→second reactive gas distributor (R2)→fourth purge gas distributor (P4)”.

Referring to FIG. 6, in an apparatus for realizing the substrate processing apparatus 1 according to an embodiment of the present invention, a plurality of reactive gas distributors R1 and R2 may be disposed, and the substrate 100 may pass through the plurality of reactive gas distributors R1 and R2 through one cycle or one-time rotation. Also, an interval between the first reactive gas distributor R1 and the second reactive gas distributor R2 may be less (shorter) than an interval between the first reactive gas distributor R1 and the second purge gas distributor P2. Alternatively, the interval between the first reactive gas distributor R1 and the second reactive gas distributor R2 may be less (shorter) than an interval between the second reactive gas distributor R2 and a fourth purge gas distributor P4.

Moreover, the first reactive gas distributor R1 and the second reactive gas distributor R2 may include the same gas. Also, the first reactive gas distributor R1 and the second reactive gas distributor R2 may differ in flow amount or flow rate.

Referring to FIG. 6, a source gas applied to the apparatus for realizing the substrate processing apparatus 1 according to an embodiment of the present invention may include a metal precursor (a Ti-containing precursor), and a reactive gas may include a nitriding gas or an oxidizing gas (an N-containing gas). In detail, the source gas may include a Zr (or Al, Hf, Ta, etc.)-containing precursor, and the reactive gas may include an O-containing gas.

Referring to FIG. 6, the source gas applied to the apparatus for realizing the substrate processing process according to an embodiment of the present invention may include a Si-containing gas (including organic silane, aminosilane, and/or the like), the reactive gas may include a nitriding gas or an oxidizing gas, and a purge gas may include a non-reactive gas. In detail, the source gas may include a Si-containing gas, and the reactive gas may include an N-containing gas or an O-containing gas.

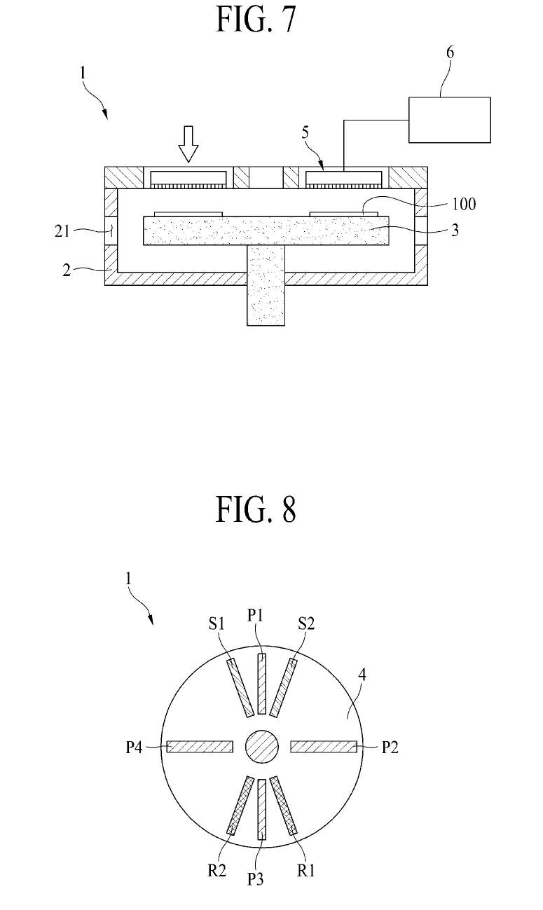

Referring to FIG. 7, a radio frequency (RF) power source/RF matcher 6 may be connected to a source gas distributor or a reactive gas distributor. By using the RF power source/RF matcher 6, plasma may be generated in a portion of a reactive space disposed in a chamber 2.

Referring to FIG. 8, in a substrate processing apparatus 1 according to an embodiment of the present invention, a first reactive gas distributor (R1) or a second reactive gas distributor (R2) may distribute a radical gas or a plasma electrode may be provided in a deposition cycle “first source gas distributor (S1)→first purge gas distributor (P1)→second source gas distributor (S2)→second purge gas distributor (P2)→first reactive gas distributor (R1)→third purge gas distributor (P3)→second plasma reactive gas distributor (R2), plasma electrode, or radical gas distribute→fourth purge gas distributor (P4)”.

Referring to FIG. 8, in the substrate processing apparatus 1 according to an embodiment of the present invention, a plurality of reactive gas distributors R1 and R2 may be disposed. In one cycle or one-time rotation, the substrate 100 may pass through the plurality of reactive gas distributors R1 and R2, and one of the reactive gas distributors R1 and R2 may distribute the radical gas, or the plasma electrode may be provided.

Referring to FIG. 8, a source gas applied to the substrate processing apparatus 1 according to an embodiment of the present invention may include a metal precursor (a Ti-containing precursor), and a reactive gas may include a nitriding gas or an oxidizing gas (an N-containing gas). In detail, the source gas may include a Zr (or Al, Hf, Ta, etc.)-containing precursor, and the reactive gas may include an O-containing gas.

Referring to FIG. 8, the source gas applied to the apparatus for realizing the substrate processing process according to an embodiment of the present invention may include a Si-containing gas (including organic silane, aminosilane, and/or the like), the reactive gas may include a nitriding gas or an oxidizing gas, and a purge gas may include a non-reactive gas. In detail, the source gas may include a Si-containing gas, and a first reactive gas and a second reactive gas may differ in atomic weight. In detail, the source gas may include a Si-containing gas, the first reactive gas distributor R1 may generate ozone (O₃), and the second reactive gas distributor R2 may generate oxygen (O₂) plasma. In detail, the source gas may include a Si-containing gas, the first reactive gas distributor R1 may generate oxygen (O₂), and the second reactive gas distributor R2 may generate plasma including carbon (C) and hydrogen (H).

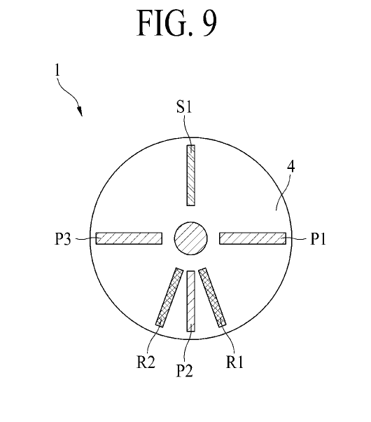

Referring to FIG. 9, a substrate processing apparatus 1 according to an embodiment of the present invention may perform a thin film deposition method which use a deposition cycle “first source gas distributor (S1)→first purge gas distributor (P1)→first reactive gas distributor (R1)→second purge gas distributor (P2)→second reactive gas distributor (R2)→third purge gas distributor (P3)”.

Referring to FIG. 9, in an apparatus for realizing the substrate processing apparatus 1 according to an embodiment of the present invention, a plurality of reactive gas distributors R1 and R2 may be disposed, and the substrate 100 may pass through the plurality of reactive gas distributors R1 and R2 through one cycle or one-time rotation. Also, an interval between reactive gas distributors (the first reactive gas distributor R1 and the second reactive gas distributor R2) may be less than an interval between a source gas distributor (the first source gas distributor S1) and a purge gas distributor (the first purge gas distributor P1 or the third purge gas distributor P2). Also, the first reactive gas distributor R1 and the second reactive gas distributor R2 may include the same gas. Also, the first reactive gas distributor R1 and the second reactive gas distributor R2 may differ in flow amount or flow rate.

Referring to FIG. 9, a source gas applied to the apparatus for realizing the substrate processing apparatus 1 according to an embodiment of the present invention may include a metal precursor (a Ti-containing precursor), and a reactive gas may include a nitriding gas or an oxidizing gas (an N-containing gas). In detail, the source gas may include a Zr (or Al, Hf, Ta, etc.)-containing precursor, and the reactive gas may include an O-containing gas.

Referring to FIG. 9, the source gas applied to the apparatus for realizing the substrate processing process according to an embodiment of the present invention may include a Si-containing gas (including organic silane, aminosilane, and/or the like), the reactive gas may include a nitriding gas or an oxidizing gas, and a purge gas may include a non-reactive gas. In detail, the source gas may include a Si-containing gas, and the reactive gas may include an N-containing gas or an O-containing gas. In detail, the source gas may include a Si-containing gas, the first reactive gas distributor R1 may generate ozone (O₃), and the second reactive gas distributor R2 may generate oxygen (O₂) plasma. In detail, the source gas may include a Si-containing gas, the first reactive gas distributor R1 may generate oxygen (O₂), and the second reactive gas distributor R2 may generate plasma including carbon (C) and hydrogen (H).

According to the embodiments of the present invention, a deposition process and a treatment process may be performed through one cycle or one-time rotation, and repetitive rotation may be performed a plurality of times. Also, a deposition film including the same source and a deposition film including different sources may be deposited simultaneously or sequentially. Also, the same deposition film may be deposited through two-time rotation, and different films may be deposited through three-time rotation. That is, deposition films may be non-sequentially deposited. Also, the same film or different films may be alternately deposited.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. An apparatus for processing a substrate, the apparatus comprising:
a chamber;
a susceptor disposed in a lower portion of the chamber, at least one substrate being disposed on the susceptor;
a chamber lid disposed on the susceptor;
a first source gas distributor installed in the chamber lid to distribute a source gas;
a second source gas distributor installed in the chamber lid to distribute a source gas; and
a first purge gas distributor installed in the chamber lid to distribute a purge gas, the first purge gas distributor being installed between the first and second source gas distributors.

2. The apparatus of claim 1, wherein the source gas comprises one of a Si-containing gas, a Ti-containing precursor, Zr, Al, Hf, and Ta.

3. The apparatus of claim 1, wherein the first source gas distributor, the second source gas distributor, and the first purge gas distributor installed in the chamber lid are radially installed in a direction toward an outer portion with respect to a center portion of the chamber lid.

4. The apparatus of claim 3, wherein an interval between center portions of the first source gas distributor and the first purge gas distributor installed in the chamber lid is shorter than an interval between outer portions of the first source gas distributor and the first purge gas distributor.

5. The apparatus of claim 1, further comprising:
a second purge gas distributor installed in the chamber lid to distribute a purge gas; and
a third purge gas distributor installed in the chamber lid to distribute a purge gas.

6. The apparatus of claim 5, wherein a gas distribution area of the second purge gas distributor or the third purge gas distributor is wider than a gas distribution area of the first purge gas distributor.

7. The apparatus of claim 5, wherein a gas distribution flow rate of the second purge gas distributor or the third purge gas distributor is higher than a gas distribution flow rate of the first purge gas distributor.

8. The apparatus of claim 1, further comprising: a plurality of reactive gas distributors installed in the chamber lid to distribute a reactive gas.

9. The apparatus of claim 8, wherein the reactive gas comprises a nitrogen-containing gas or an oxygen-containing gas.

10. The apparatus of claim 8, wherein the plurality of reactive gas distributors each comprise a plasma electrode.

11. A method of for processing a substrate, the method comprising:
loading at least one substrate on a substrate supporting part installed in a chamber;
distributing a source gas through a first source gas distributor installed on the at least one substrate;
distributing a purge gas through a first purge gas distributor installed on the at least one substrate; and
distributing a source gas through a second source gas distributor installed on the at least one substrate,
wherein the distributing of the source gas through the first source gas distributor, the distributing of the purge gas through the first purge gas distributor, and the distributing of the source gas through the second source gas distributor are sequentially performed on the at least one substrate.

12. The method of claim 11, wherein the source gas comprises one of a Si-containing gas, a Ti-containing precursor, Zr, Al, Hf, and Ta.

13. The method of claim 11, further comprising: distributing a reactive gas through a plurality of reactive gas distributors installed in a chamber lid.

14. The method of claim 13, wherein the reactive gas comprises a nitrogen-containing gas or an oxygen-containing gas.

15. The method of claim 13, wherein each of the plurality of reactive gas distributors generates plasma or a radical gas.

16. The method of claim 11, further comprising: distributing a purge gas through a second purge gas distributor and a third purge gas distributor installed in a chamber lid.

17. The method of claim 16, wherein a gas distribution area of the second purge gas distributor or the third purge gas distributor is wider than a gas distribution area of the first purge gas distributor.

18. The method of claim 16, wherein a gas distribution flow rate of the second purge gas distributor or the third purge gas distributor is higher than a gas distribution flow rate of the first purge gas distributor.
